(19) United States
(12) Patent Application Publication
(10) Pub. No.: US 2024/0364314 A1
(43) Pub. Date: Oct. 31, 2024

(54) METHOD AND APPARATUS FOR DYNAMIC RF POWER SPLITTING THROUGH MANIPULATION OF DC OUTPUT PROPERTIES

(71) Applicant: Powercast Corporation, Pittsburgh, PA (US)

(72) Inventors: Jason Arthur GILL, Pittsburgh, PA (US); John Robert RONEY, Renfrew, PA (US); Sam James DEANE, Pittsburgh, PA (US); Charles Edward GREENE, Butler, PA (US); Eric James BIEL, Glenshaw, PA (US)

(73) Assignee: Powercast Corporation, Pittsburgh, PA (US)

(21) Appl. No.: 18/767,680

(22) Filed: Jul. 9, 2024

Related U.S. Application Data
(63) Continuation of application No. PCT/US2024/010367, filed on Jan. 4, 2024.
(60) Provisional application No. 63/437,109, filed on Jan. 4, 2023.

(51) Int. Cl. H03H 11/30; H02J 50/00; H02J 50/20; H03H 2/00

(52) U.S. Cl. CPC H03H 11/30; H02J 50/001; H02J 50/20; H03H 2/008

(57) ABSTRACT

In some embodiments, an apparatus includes an antenna; a radio-frequency (RF) tuning network configured to receive an input signal via the antenna; an RF energy harvester operatively coupled to the RF tuning network and configured to produce a direct current (DC) output based on the received output of the RF tuning network; and a load manipulator configured to be transitioned between a first configuration and a second configuration to manipulate one or more properties associated with the RF energy harvester such that an input impedance of the RF energy harvester changes from a first input impedance to a second input impedance. The first input impedance is associated with a first distribution of RF energy associated with the input signal relative to the RF energy harvester and the second input impedance is associated with a second distribution of RF energy associated with the input signal relative to the RF energy harvester.

### CROSS-REFERENCE TO RELATED APPLICATIONS

This application is a continuation of International Patent Application No. PCT/US2024/010367, entitled “Method and Apparatus for Dynamic RF Power Splitting Through Manipulation of DC Output Properties,” filed Jan. 4, 2024, which claims priority to and the benefit of U.S. Provisional Patent Application No. 63/437,109, entitled “Method and Apparatus for Dynamic RF Power Splitting Through Manipulation of DC Output Properties,” filed Jan. 4, 2023, the disclosure of each of which is incorporated by reference herein in its entirety.

### BACKGROUND

Some embodiments described herein relate generally to systems, methods, and apparatus for controlling the distribution of radio-frequency (RF) power within or by RF energy harvesting systems.

Known RF switches at the characteristic impedance of an energy harvesting system can be controlled by a microcontroller or another device to control power distribution within or by the energy harvesting system. RF switches, however, tend to add cost, size, and/or complexity to the system design. Known energy harvesting systems can include a passive RF tuning network used to split power between separate components within the energy harvesting system, but the power split in such energy harvesting systems is fixed and cannot be dynamically changed. Another approach is to include multiple antennas in a known energy harvesting system, with each antenna associated with a distinct harvester or load so that more than one harvester and/or load in the energy harvesting system can receive energy. Such an approach can increase the overall size, cost and complexity of the system design, and special care may be needed to avoid interference between the antennas.

Thus, a need exists for an RF energy harvesting system that is configured to distribute RF power internally and/or externally as desired, that avoids the downsides of existing power distribution methods, and that allows for dynamic control of RF power splitting.

### SUMMARY

In some embodiments, an apparatus includes an antenna, a radio-frequency (RF) tuning network, an RF energy harvester, and a load manipulator. The RF tuning network can be configured to receive an input signal via the antenna. The RF energy harvester can be operatively coupled to the RF tuning network and configured to receive an output of the RF tuning network and to produce a direct current (DC) output based on the received output of the RF tuning network. The load manipulator can be coupled to an output of the RF energy harvester and configured to be transitioned between a first configuration and a second configuration to manipulate one or more properties associated with the RF energy harvester such that an input impedance of the RF energy harvester changes from a first input impedance to a second input impedance. The first input impedance can be associated with a first distribution of RF energy associated with the input signal relative to the RF energy harvester and the second input impedance can be associated with a second distribution of RF energy associated with the input signal relative to the RF energy harvester.

### BRIEF DESCRIPTION OF THE DRAWINGS

FIG. 1 is a schematic illustration of an energy harvesting system, according to an embodiment.

FIG. 2 is a schematic illustration of an energy harvesting system, according to an embodiment.

FIG. 3 is a schematic illustration of an energy harvesting system, according to an embodiment.

FIG. 4 is a schematic illustration of an energy harvesting system, according to an embodiment.

FIG. 5 is a schematic illustration of an energy harvesting system, according to an embodiment.

FIG. 6 is a flowchart of a method for harvesting energy, according to an embodiment.

### DETAILED DESCRIPTION

In some embodiments, an apparatus includes an antenna, a radio-frequency (RF) tuning network, an RF energy harvester, and a load manipulator. The RF tuning network can be configured to receive an input signal via the antenna. The RF energy harvester can be operatively coupled to the RF tuning network and configured to receive an output of the RF tuning network and to produce a direct current (DC) output based on the received output of the RF tuning network. The load manipulator can be coupled to an output of the RF energy harvester and configured to be transitioned between a first configuration and a second configuration to manipulate one or more properties associated with the RF energy harvester such that an input impedance of the RF energy harvester changes from a first input impedance to a second input impedance. The first input impedance can be associated with a first distribution of RF energy associated with the input signal relative to the RF energy harvester and the second input impedance can be associated with a second distribution of RF energy associated with the input signal relative to the RF energy harvester.

In some embodiments, an apparatus includes an antenna, a radio-frequency (RF) tuning network, an RF energy harvester, and a set of one or more components configured to receive RF energy. The RF tuning network can be configured to receive an input signal via the antenna. The RF energy harvester can be operatively coupled to the RF tuning network and configured to receive an output of the RF tuning network and to produce a direct current (DC) output based on the received output of the RF tuning network in response to the RF energy harvester having a first input impedance. The set of one or more components can be configured to receive RF energy reflected or directed from the RF energy harvester in response to the RF energy harvester having a second input impedance. A DC output of the RF energy harvester can be configured to be manipulated to transition the RF energy harvester from having the first input impedance to having the second input impedance. In some embodiments, the set of one or more components can include, for example, an RF device, an RF tuning network, an RF energy harvester, an RF communication device, and/or a circuit such as radio frequency identification (RFID) integrated Circuit (IC).

In some embodiments, a method includes manipulating, at a first time, one or more properties associated with a radio-frequency (RF) energy harvester such that an input impedance of the RF energy harvester changes from a first input impedance to a second input impedance to produce a first distribution of RF energy relative to the RF energy harvester. The RF energy can be associated with an input signal received by the RF energy harvester via an antenna operable coupled thereto. At a second time, the one or more properties associated with the RF energy harvester can be manipulated such that an input impedance of the RF energy harvester changes from the second input impedance to a third input impedance. The third input impedance can be associated with a second distribution of the RF energy relative to the RF energy harvester.

In some embodiments, an energy harvesting system can include one or more RF energy harvesters that each has an input impedance associated with a distribution (e.g., a direction and/or reflection) of incident RF power within the energy harvesting system. The input impedance of each of the one or more RF energy harvesters can change in response to a change in one or more properties (e.g., one or more parameters) of the energy harvesting system including the one or more RF energy harvesters. For example, the harvester direct current (DC) output voltage, the operating frequency, the incident RF input power, and other parameters of the energy harvesting system can affect the input impedance of an RF energy harvester. Thus, a distribution (e.g., a direction and/or reflection) of incident RF power within the energy harvesting system can be controlled by altering one or more of the system parameters, either individually or as a combination of multiple parameters, to change (e.g., manipulate) the input impedance of each of the one or more RF energy harvesters.

In some embodiments, by changing the input impedance of an RF energy harvester within an energy harvesting system, the amount of RF energy that is directed to the RF energy harvester and the amount of RF energy that is reflected away from the input of the RF energy harvester can be controlled. In some embodiments, changing the input impedance of an RF energy harvester within an energy harvesting system can cause RF power to be reflected or directed to one or more RF devices connected in parallel or in series to the RF energy harvester or reflected back to an antenna (e.g., an antenna through which the RF energy was initially received) for communication purposes (e.g., backscatter communication). In some embodiments, systems and methods described herein allow for dynamic control of RF power splitting by manipulating the DC output properties of an RF energy harvester.

One or more embodiments of RF energy harvesters described herein have an input impedance that can be manipulated in at least one of several ways to control the amount of RF energy received into the RF energy harvester and/or the amount of RF energy reflected away from the input of the RF energy harvester. For example, one or more system properties (e.g., parameters) of an energy harvesting system including an antenna, a front-end tuning network (also referred to as an RF tuning network), and an RF energy harvester can be modified to create an impedance mismatch between the antenna and the RF energy harvester such that energy is reflected or directed from the input of the RF energy harvester. Specifically, in some embodiments, an energy harvesting system can include a front-end tuning network that is configured to match an impedance of an antenna of the system to an input impedance of the RF energy harvester at one specific set of system parameters (e.g., frequency, input power, and/or DC load voltage) for maximum power transfer. When one or more of these system parameters are changed without changing the tuning network (e.g., without a change in the RF tuning network 320 to account for the change in the input impedance), an impedance mismatch between the RF energy harvester and the antenna may be created, reducing system efficiency and changing the distribution of energy relative to the RF energy harvester.

As another example, a load of an RF energy harvester of a system can be changed to control (e.g., adjust) the input impedance of the RF energy harvester, thus changing the flow of RF energy relative to the RF energy harvester. For example, in some embodiments, a DC output of an RF energy harvester in a system (e.g., an energy harvesting system) can be changed by switching (e.g., replacing, removing, and/or adding) different load devices into the system (e.g., into electrical connection with the RF energy harvester). Thus, in some embodiments, different loads can include load devices in common. The load devices can include, for example, passive loads, such as one or more resistors, capacitors, and/or inductors. The load devices can also include, for example, energy storage devices (e.g., a battery or a solar cell) at different voltages.

In some embodiments, one or more load devices electrically coupled to the RF energy harvester can be switched, enabled, disabled, and/or otherwise controlled by a controller (e.g., a digital or analog controller) included in the system and configured to control the relationship between the RF energy harvester and the one or more load devices (e.g., by controlling a status of one or more switches) based, at least in part, on an intended input impedance of the RF energy harvester.

In some embodiments, the output voltage of the RF energy harvester can also be changed by using direct current to direct current (DC-to-DC) converters (e.g., including one or more DC-to-DC converters in the system electrically coupled to the RF energy harvester such as to an output of the RF energy harvester) to raise or lower the output voltage or by using a digital-to-analog converter (e.g., included in the system and electrically coupled to the RF energy harvester) to digitally control the output voltage present at the output of the RF energy harvester.

In some embodiments, an RF energy harvesting system can include an RF source (e.g., an antenna), a tuning network (also referred to as a matching network), an energy harvester, and/or a load. The load can include passive component(s), energy storage device(s), any type of DC/DC converter(s), and/or any combination thereof. The tuning network can include passive and/or active components. In some embodiments, one or more devices can be included in or coupled to the system, can use (e.g., be electrically coupled to) the same RF source, and/or can be connected in parallel, series, and/or other configurations. Each device may or may not have their own tuning network and/or load with which the device can be associated. The one or more devices can include RF devices such as an RF energy harvester, an RF communication device, and/or a radio frequency identification (RFID) integrated Circuit (IC). The one or more devices can include, for example, one or more RF-DC converters, one or more processors, one or more memories, one or more energy storage devices, one or more tuning networks, and/or any other suitable circuits or components. For example, in some embodiments, a system, such as any of the systems described herein, can include an RF energy harvester with its own tuning network connected in parallel with a radio frequency identification (RFID) integrated Circuit (IC) with its own tuning network, both connected to a single antenna.

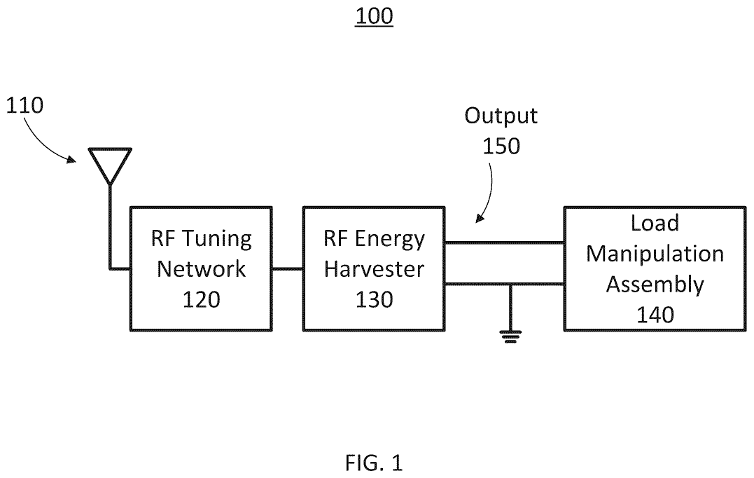

As an example, FIG. 1 is a schematic illustration of an energy harvesting system 100. The system 100 can the same or similar in structure and/or function to any of the systems described herein. The system 100 includes an antenna 110, an RF tuning network 120, an RF energy harvester 130, and a load manipulation assembly 140 (also referred to as a load manipulator) coupled to an output 150 of the RF energy harvester 130.

The load manipulation assembly 140 can include one or more components configured to manipulate one or more DC output properties of the RF energy harvester 130 to change the input impedance of the RF energy harvester 130. For example, in some embodiments, the load manipulation assembly 140 can include a set of one or more load devices configured to be selectively electrically coupled to the output 150 of the RF energy harvester 130 in various combinations. As described above, in some embodiments, the load coupled to the output of the RF energy harvester can be manipulated by changing which of a set of load devices are disposed in electrical connection with the output 150 of the RF energy harvester 130. For example, one or more load devices can be switched (e.g., replaced, removed, and/or added) into electrical connection with the output 150 of the RF energy harvester 130. In some embodiments, one or more of the one or more load devices can be physically removed and/or added to the system 100 and/or can be physically connected to and/or disconnected from the output 150 (e.g., by a user) to change the load coupled to the output 150. In some embodiments, one or more of the one or more load devices can be transitioned into and/or out of electrical connection with the output 150 to change the load coupled to the output 150 without any physical movement of the load device(s) relative to the output 150, such as via transitioning circuitry and/or components thereof associated with each load device and the output 150 between connecting and disconnecting states. The switching can be controlled, for example, by one or more controllers and/or switches coupled or included in the system 100 (not shown). The one or more controllers and/or switches and/or the load devices configured to be selectively coupled to the output 150 of the RF energy harvester can optionally be included in or coupled to the load manipulation assembly 140. The one or more controllers and/or switches can be configured to allow for dynamic control of the power splitting of the system 100 (e.g., relative to the input of the RF energy harvester 130). The one or more controllers can each include, for example, one or more processors (e.g., a general processor or an application specific processor) and/or one or more circuits (e.g., an application-specific integrated circuit (ASIC)). In some embodiments, the one or more processors can be configured to run software and/or code to perform any of the functions described herein.

The RF energy harvester 130 can be configured to receive energy (e.g., carried by an input signal) from the antenna 110 via the RF tuning network 120. The RF energy harvester 130 can be operatively coupled to the RF tuning network 120 and configured to receive an output of the RF tuning network 120. The RF energy harvester 130 can be configured to produce a direct current (DC) output based on the received output of the RF tuning network 120. For example, the RF energy harvester 130 can include one or more rectifying devices (e.g., RF-to-DC converters).

As a result of the DC output of the RF energy harvester 130 changing (e.g., under the control of the load manipulation assembly 140), the input impedance of the RF energy harvester 130 may change. The change in the input impedance of the RF energy harvester 130 may cause an impedance mismatch between the RF energy harvester 130 and the antenna 110. Therefore, instead of RF energy received by the antenna 110 being transferred to the RF energy harvester 130, some or all of the RF energy may be reflected to the antenna 110 and the antenna 110 can reradiate the RF energy. By changing the load electrically connected to the output 150 of the RF energy harvester 130 (e.g., via electrically coupling and/or uncoupling one or more load devices to the output 150 of the RF energy harvester 130) to change the DC output of the RF energy harvester 130, the reflection of RF energy to the antenna 110 can be started and stopped such that the reradiation of energy from the antenna 110 can be switched on or off. In this way, backscatter communication can be realized by changing the DC output of the RF energy harvester 130. This approach and architecture differ from known RFID backscatter communication, which typically includes a passive element coupled to the antenna that changes the impedance of an energy harvester such that some received energy can be reflected to and sent by the antenna.

In some embodiments, the load manipulation assembly 140 can be configured to be transitioned between a plurality of configurations. For example, each configuration can be associated with a different load (e.g., set or subset of one or more load devices being electrically coupled to the output 150). In some embodiments, the load manipulation assembly 140 can include any suitable number of configurations based on the combinations of load devices available. Each configuration can be associated with a different set of properties of the RF energy harvester 130 and/or with a different input impedance of the RF energy harvester 130. As described above, different input impedances of the RF energy harvester 130 can be associated with different (e.g., distinct) RF energy distributions relative to the input of the RF energy harvester 130. Thus, each configuration or load of the load manipulation assembly 140 can be associated with a particular RF energy distribution relative to the RF energy harvester 130 (e.g., to and from the RF energy harvester 130). In some embodiments, the first load can include at least one passive load device, energy storage device, or DC/DC converter and the second load can include at least one passive load device, energy storage device, or DC/DC converter.

In some embodiments, for example, the load manipulation assembly 140 can be configured to be transitioned between a first configuration and a second configuration to manipulate one or more properties associated with the RF energy harvester 130 such that an input impedance of the RF energy harvester 130 changes from a first input impedance to a second input impedance. The first input impedance can be associated with a first distribution of RF energy associated with the input signal relative to the RF energy harvester. The second input impedance can be associated with a second distribution of RF energy associated with the input signal relative to the RF energy harvester. In some embodiments, the load manipulation assembly 140 can include a third configuration associated with a third input impedance and a third distribution of RF energy, a fourth configuration associated with a fourth input impedance and a fourth distribution of RF energy, etc.

In some embodiments, each distribution of RF energy associated with a set of one or more properties of the RF energy harvester 130 and/or associated with a load electrically coupled to the output 150 of the RF energy harvester 130 can be associated with a particular ratio of an amount of energy reflected by the RF energy harvester 130 to an amount of energy directed to the RF energy harvester 130 (e.g., for conversion to DC and/or for output via the output 150). For example, a first distribution of RF energy associated with a first set of one or more properties of the RF energy harvester 130 can be associated with a first ratio of an amount of energy reflected by the RF energy harvester 130 to an amount of energy directed to the RF energy harvester 130. A second distribution of RF energy associated with a first set of one or more properties of the RF energy harvester 130 can be associated with a second ratio of the amount of energy reflected by the RF energy harvester 130 to the amount of energy directed to the RF energy harvester 130. In some embodiments, a particular distribution may include all of the energy received by the input of the RF energy harvester 130 being directed to the RF energy harvester, and another distribution may include all of the energy received by the input of the RF energy harvester 130 being reflected from the RF energy harvester, rather than a portion being directed and a portion being reflected according to a ratio based on the input impedance of the RF energy harvester 130.

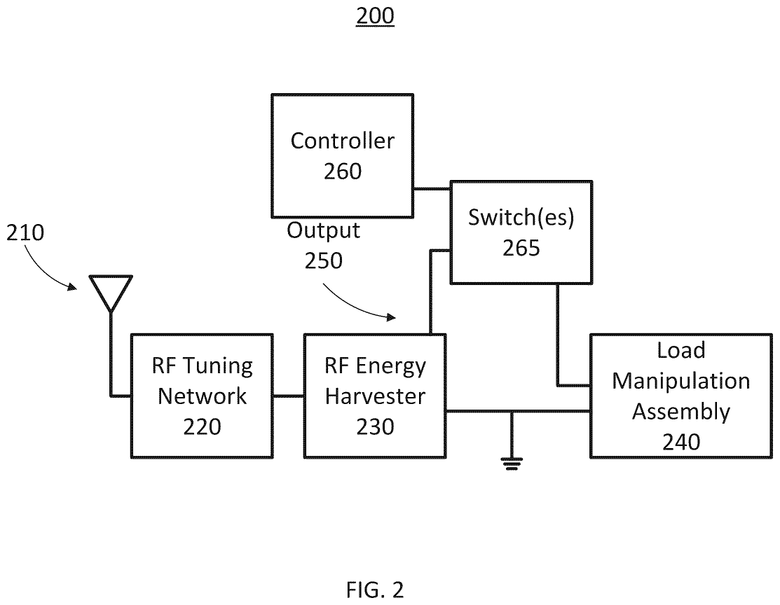

In some embodiments, as described above, an energy harvesting system, such as any of the systems described herein, can include one or more controllers operatively coupled to one or more switches and configured to control the load in electrical connection with an output of an RF energy harvester to manipulate the input impedance of the RF energy harvester. As shown in FIG. 2, for example, an energy harvesting system 200 can include an antenna 210, an RF tuning network 220, an RF energy harvester 230, and a load manipulation assembly 240 coupled to an output 250 of the RF energy harvester 230 via one or more switches 265. The system 200 can be the same or similar in structure and/or function to any of the systems described herein, such as the energy harvesting system 100 described above. The system 200 can include a controller 260 operatively coupled to the one or more switches 265 and configured to selectively control which switch or combination of switches of a set of one or more switches of the load manipulation assembly 240 is coupled to the output 250 of the RF energy harvester 230. The controller 260 and the one or more switches 265 can be the same or similar in structure and/or function to any of the controller(s) and switch(es), respectively, described herein, such as those described above with respect to the system 100. For example, the controller 260 can each include, for example, one or more processors (e.g., a general processor or an application specific processor) and/or a circuit (e.g., an application-specific integrated circuit (ASIC)). In some embodiments, the one or more processors can be configured to run software and/or code to perform any of the functions described herein.

Although shown separately in FIG. 2, in some embodiments, the load manipulation assembly 240 can include the controller 260 and the one or more switches 265. As an example, in some embodiments, the controller 260 can selectively electrically couple a first load to the output 250 of the RF energy harvester 230 in a first configuration of the load manipulation assembly 240 and can selectively electrically couple a second load to the output 250 of the RF energy harvester 230 in a second configuration of the load manipulation assembly 240. The first configuration can be associated with a first input impedance of the RF energy harvester 230 and the second configuration can be associated with a second input impedance of the RF energy harvester 230. In some embodiments, the one or more switches 265 can include at least one switch configured to transition the load manipulation assembly 240 between the first configuration and the second configuration by selectively coupling one or more loads of the load manipulation assembly 240 to the output 250 of the RF energy harvester 230. In some embodiments, the controller 260 can be operatively coupled to the one or more switches 265 and configured to control a status of each switch of the one or more switches 265 to control the selective coupling of one or more loads or one or more load devices to the output 250 of the RF energy harvester 230.

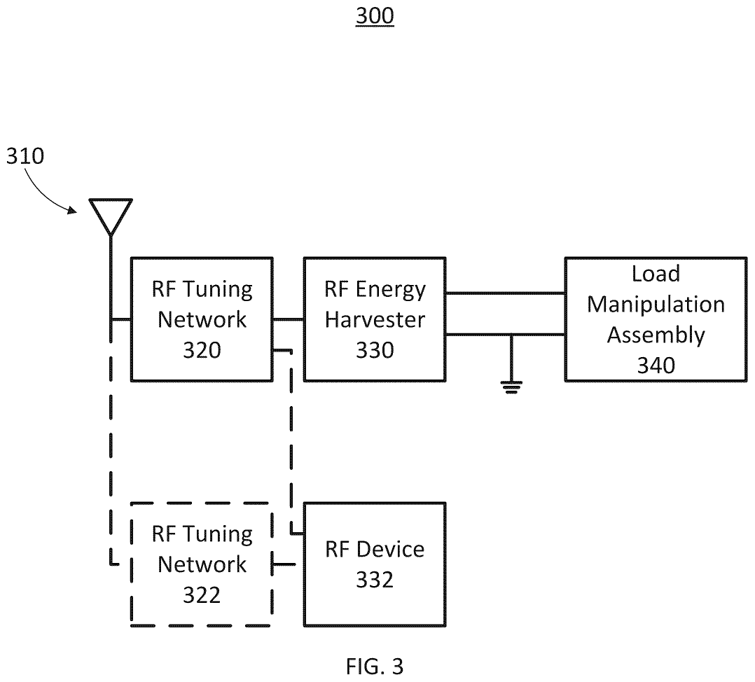

In some embodiments, an energy harvesting system including RF devices using (e.g., coupled to and receiving RF energy via) the same RF source (e.g., the same antenna) can be coupled in parallel and each RF device can optionally be associated with (e.g., coupled to and configured to receive signals from) their own front-end tuning network to which that RF device is coupled, with at least one of the devices being an RF energy harvester. For example, FIG. 3 is a schematic illustration of an energy harvesting system 300. The system 300 includes an antenna 310, an RF tuning network 320, an RF energy harvester 330, and a load manipulation assembly 340. The system 300 can be the same or similar in structure and/or function to any of the systems described herein, such as the energy harvesting system 100 and/or the energy harvesting system 200 described above. The system 300 also includes an RF device 332, which can optionally be an RF energy harvester (also referred to as a “second RF energy harvester”), coupled to the antenna 310 in parallel with the RF energy harvester 330 such that both the RF energy harvester 330 and the RF device 332 can receive energy from the antenna 310 (e.g., via an RF input signal). As shown, the RF device 332 can optionally be associated with (e.g., a coupled to the antenna 310 via) a dedicated RF tuning network 322 and/or can be coupled to the RF tuning network 320 to receive energy (e.g., via an RF input signal) from the antenna 310 via the RF tuning network 320. The RF device 332 can optionally be the same or similar in structure and/or function to any of the RF devices described herein, such as any of the RF energy harvesters described herein. In some embodiments, the RF device 332 and the RF tuning network can be considered to be included in a set of one or more components configured to receive RF energy in addition to the RF tuning network 320 and the RF energy harvester 330. In some embodiments, the RF device 332 can include any suitable RF devices or circuits, such as an RF energy harvester, an energy storage device, an RFID IC (e.g., an RFID ASIC), and/or an RFID tag. The RF device 332 can include, for example, a processor, a memory, and, optionally, an RF transmitter, an RF receiver, and/or an RF transceiver. The RF device 332 can also configured to operate based on received RF energy and/or use received RF energy for communication purposes.

In response to the DC output of the RF energy harvester 330 changing (e.g., under the control of the load manipulation assembly 340), the input impedance of the RF energy harvester 330 can change. The change in the input impedance of the RF energy harvester 330, without a change in the RF tuning network 320 to account for the change in the input impedance, may cause an impedance mismatch between the RF energy harvester 330 and the antenna 310, as well as between the RF energy harvester 330 and the RF device 332 and/or any other RF devices included in the system. The impedance mismatch may cause more or less power to be directed to the RF energy harvester 330, therefore also directing (e.g., reflecting) more or less power to the RF device 332, other devices in the system 300, and/or to the antenna 310. Thus, in such a system (e.g., a system including a harvester and one or more other devices coupled in parallel and to a common antenna such as the system 300), the amount of power provided to RF devices coupled in parallel to the RF energy harvester (e.g., the RF energy harvester 330) can be controlled by controlling the DC output of the RF energy harvester 330.

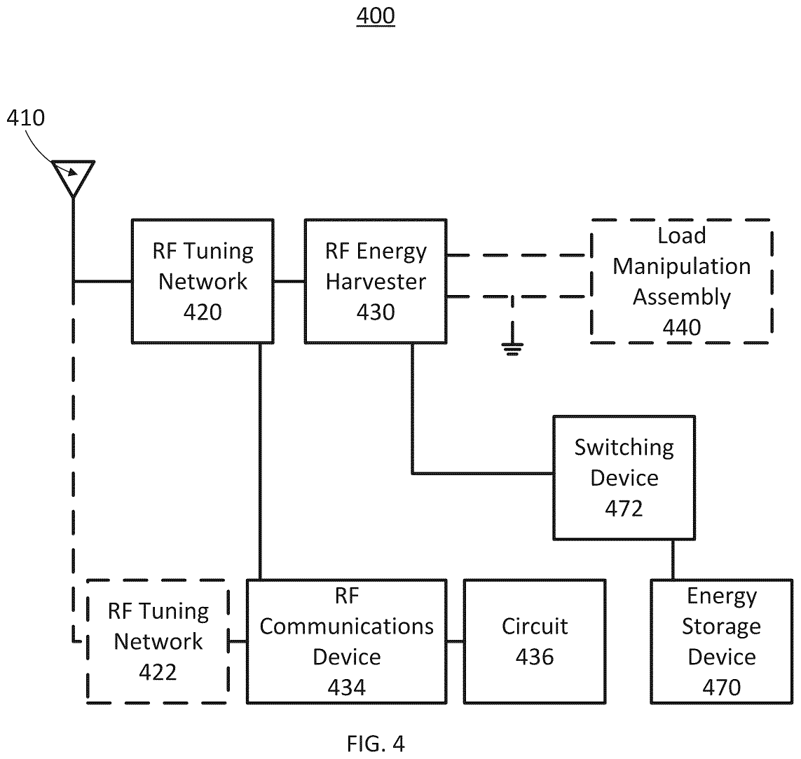

In some embodiments, such as any of the energy harvesting systems and/or methods described herein, changing the input impedance of a harvester to control distribution of energy within the system can be used to prolong the battery life of one or more RF devices included in the system. In some embodiments, as shown in FIG. 4, for example, an energy harvesting system 400 can include an antenna 410, an RF tuning network 420, an RF energy harvester 430 electrically coupled in parallel with an RF communications device 434 (e.g., an RF backscatter device), a circuit to be powered 436, and an energy storage device 470. The system 400 can optionally include a load manipulation component 440 coupled to an output of the RF energy harvester 430 that can be same or similar in structure and/or function to any of the load manipulation components described herein.

The energy storage device 470 can be initially disabled and/or electrically decoupled from the system 400 or a remainder of the system 400 (e.g., via any suitable switching device 472) (e.g., from the RF energy harvester 430), and all received RF power can be initially directed to the RF energy harvester 430 (e.g., via the RF tuning network 420). In response to incident RF energy being detected and/or harvested by the RF energy harvester 430, the energy storage device 470 can be electrically connected and/or enabled relative to the system (e.g., the RF energy harvester 430 can “switch on” the system by connecting and/or enabling the energy storage device 470 in response to detecting and/or harvesting RF energy, such as by providing energy to the energy storage device 470). The connection and/or enablement of the energy storage device 470 within the system 400 can change the output voltage of the RF energy harvester 430, causing the input impedance of the RF energy harvester 430 to change. In response to the change in the input impedance of the RF energy harvester 430, the energy distribution relative to the RF energy harvester 430 can change so that some or all of the power received by the system 400 (e.g., received via the antenna 410 of the system 400 and provided to the input of the RF energy harvester 430 by the RF tuning network 420) is directed to the RF communications device 434 rather than being directed to the RF energy harvester 430. Thus, the system 400 can allow for the RF energy harvester 430 to activate and/or provide energy to increase a stored power level in an energy storage device 470 for a first period of time, and then to provide energy to the RF communications device 434 for a second period of time (e.g., after activation of the suitable switching device 472 and/or the energy storage device 470 and/or during or after increasing the stored power level). Such a system 400 and method allows the system 400 to remain off to preserve battery life when no or insufficient RF energy is present, and then to direct some or all of the power received by the system 400 (e.g., by an antenna 410 of the system 400) to the RF communications device 434 for communication when sufficient RF energy is present. This is accomplished using only one antenna 410 and eliminates the need for expensive RF switches.

As shown in FIG. 4, the RF communications device 434 can have an input coupled to an output of the RF tuning network 420 such that the RF communications device 434 can receive an output of the RF tuning network 420 (e.g., at least a portion of an input signal received via the antenna 410 or at least a portion of a tuned input signal provided by the RF tuning network 420 based on an input signal received via the antenna 410). Optionally, in some embodiments, rather than sharing the RF tuning network 420 with the RF energy harvester 430, the RF tuning network 420 can be a first RF tuning network 420 and the RF communications device 434 can have an input coupled to an output of a second RF tuning network 422 optionally included in the system 400. The RF communications device 434 can receive an output of the second RF tuning network 422 (e.g., at least a portion of an input signal received via the antenna 410 or at least a portion of a tuned input signal provided by the RF tuning network 422 based on an input signal received via the antenna 410). Each of the RF tuning network 420 and the second RF tuning network 422 can be the same or similar in structure and/or function to any of the tuning networks described herein.

Although shown and described with respect to the energy storage device 470 and the RF communication device 434, any suitable RF devices or circuits can be coupled to the output of the RF energy harvester 430 and/or coupled to the antenna 410 in parallel to the RF energy harvester 430 (e.g., via the RF tuning network 420 or via a separate RF tuning network 422). For example, rather than or in addition to the switching device 472 and the energy storage device 470, the system 400 can include an RF circuit or device that is activated by the RF energy harvester 430 (e.g., via receiving DC power from the RF energy harvester 430). The system 400 can also include any suitable RF devices (e.g., energy storage device(s) or circuits) instead of or in addition to the RF communications device 434 and/or the circuit 436 shown in FIG. 4 and configured to receive RF energy directed from the input of the RF energy harvester 430 after a change in input impedance of the RF energy harvester 430 caused by the activation of the RF device or circuit electrically coupled to the output of the RF energy harvester 430. In some embodiments, the RF communications device 434 and the circuit 436 can be included in an RFID IC. In some embodiments, the RF communications device 432, the RF tuning network 422, and/or the circuit 436 can be considered to be included in a set of one or more components configured to receive RF energy in addition to the RF tuning network 420 and the RF energy harvester 430.

In some embodiments, a harvester circuit can be used to charge an energy storage device. When an energy storage device is fully charged, an energy harvesting system (e.g., a receiving device or a system included in a receiving device) including an antenna, the energy storage device, and a harvester can change (e.g., switch) the harvester input impedance via changing the DC output voltage as described herein to cause an impedance mismatch which may cause RF power (e.g., the majority of RF power) to be reflected back to the antenna to be reradiated. This lets the reradiated RF energy be available for use in powering and/or charging other devices. Without this technique, when the energy storage device was fully charged, additional received power may be directed towards a resistor, LED, or some other device included in the system to absorb the excess energy and prevent overcharging of the energy storage device. By changing the DC output voltage of the harvester to change the harvester input impedance and cause an impedance mismatch between the harvester and the antenna, the excess energy can be reradiated by the system (e.g., the receiving device) and received and used by other devices (e.g., RF devices requiring that energy).

In some embodiments, the energy harvesting systems and methods described herein allow for dynamic power switching between an RF energy harvester and one or more other RF devices coupled in parallel, series, or in other combinations and all using the same RF source (e.g., antenna) by causing an impedance mismatch between the harvester, the RF source, and any other connected RF devices. The impedance mismatch is brought about by taking advantage of the property that the harvester changes its RF input impedance when the DC output voltage is changed. This is achieved without the need for multiple antennas, RF switches, or other complicated, expensive, or large solutions.

In some embodiments, the systems and methods described herein allow RF backscatter communication without the need for a separate RF backscatter integrated circuit (IC) or RF switching. The backscatter communication is brought about by an impedance mismatch between the antenna and harvester caused by the changing of the DC output voltage of the harvester.

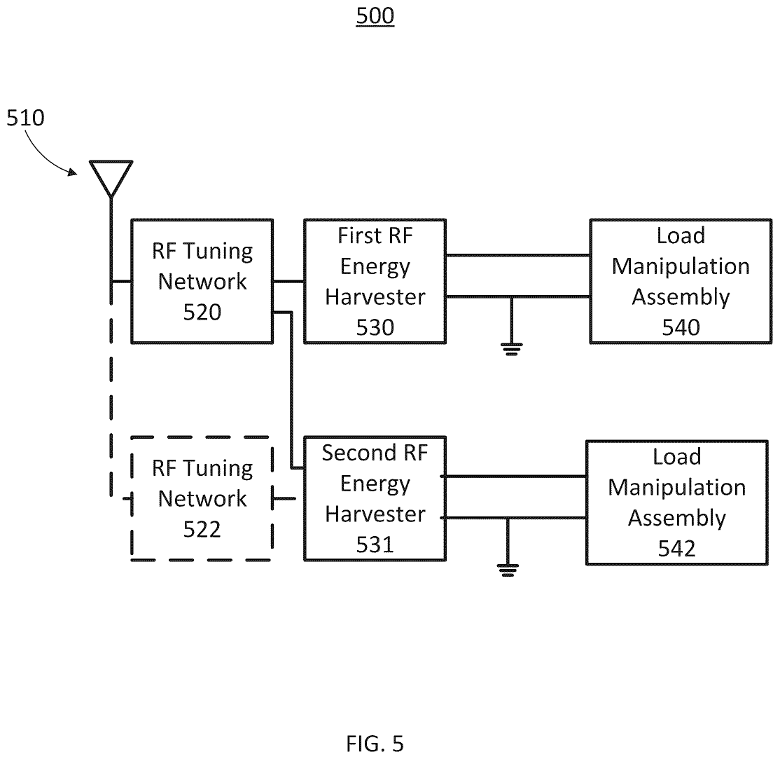

In some embodiments, multiple RF harvesters can be connected in parallel, and each may or may not have its own impedance matching or tuning network. For example, as shown in FIG. 5, a system 500 can include an antenna 510 and a first RF energy harvester 530 and a second RF energy harvester 531 coupled in parallel to the antenna 510. Each of the first RF energy harvester 530 and the second RF energy harvester 531 can be tuned to have peak efficiency at different input power levels spanning a range of possible input powers. Based on the input power to the system 500, one harvester (e.g., the first RF energy harvester 530) may have the peak efficiency and all other harvesters connected in parallel (e.g., the second RF energy harvester 531 and any additional optional RF energy harvesters coupled in parallel but not shown in FIG. 5) may diminish the overall efficiency of the system 500 by effectively robbing the desired harvester of additional RF power. By dynamically controlling the harvesters' DC outputs (and thus their input impedances) as described herein, each harvester not being used or having lower efficiency than one or more other harvesters for a particular set of input parameters associated with energy flowing to the harvester can reflect the RF energy that the harvester would normally receive back for use by other, more efficient harvesters. As shown, each of the first RF energy harvester 530 and the second RF energy harvester 531 can have an output coupled to a separate load manipulation assembly 540 and load manipulation assembly 542, respectively, which can each be the same or similar in structure and/or function to nay of the load manipulation assemblies described herein.

As shown in FIG. 5, in some embodiments, the second RF energy harvester 531 can have an input coupled to an output of the RF tuning network 520 such that the second RF energy harvester 531 can receive an output of the RF tuning network 520 (e.g., at least a portion of an input signal received via the antenna 510 or at least a portion of a tuned input signal provided by the RF tuning network 520 based on an input signal received via the antenna 510). Optionally, in some embodiments, rather than sharing the RF tuning network 520 with the RF energy harvester 530, the RF tuning network 520 can be a first RF tuning network 520 and the second RF energy harvester 531 can have an input coupled to an output of a second RF tuning network 522 optionally included in the system 500. The second RF energy harvester 531 can receive an output of the second RF tuning network 522 (e.g., at least a portion of an input signal received via the antenna 510 or at least a portion of a tuned input signal provided by the RF tuning network 522 based on an input signal received via the antenna 510). Each of the first RF tuning network 520 and the second RF tuning network 522 can be the same or similar in structure and/or function to any of the tuning networks described herein. In some embodiments, the second RF energy harvester 532 and the RF tuning network 522 can be considered to be included in a set of one or more components configured to receive RF energy in addition to the RF tuning network 520 and the RF energy harvester 530.

In some embodiments, the harvesters of the multiple RF harvesters disposed in parallel in a system that are tuned for higher input powers will not turn on and begin harvesting until the power input is raised. Therefore, as soon as a harvester turns on, that harvester may change the impedance of all harvesters tuned for lower input powers by manipulating the DC loads electrically coupled to the other harvesters, thus reflecting their power back to the harvester that is on.

In some embodiments, the impedance of a harvester may be set by the physical design of the harvester to be resonant with an external inductor or capacitor at a particular frequency and input power level. Multiple harvesters set to be resonant with the same external inductor or capacitor at different input power levels can be electrically connected in parallel. The harvester with the highest efficiency at a certain input power level will remain on and harvesting, while the other harvesters input impedances can be set (e.g., adjusted) high by manipulating the output voltage of the other harvesters. As the input power changes, the harvester of the set of harvesters that is most efficient can be used while the others can be set to high impedance. This lets the overall system efficiency remain high across a range of input powers while using a single external inductor or capacitor.

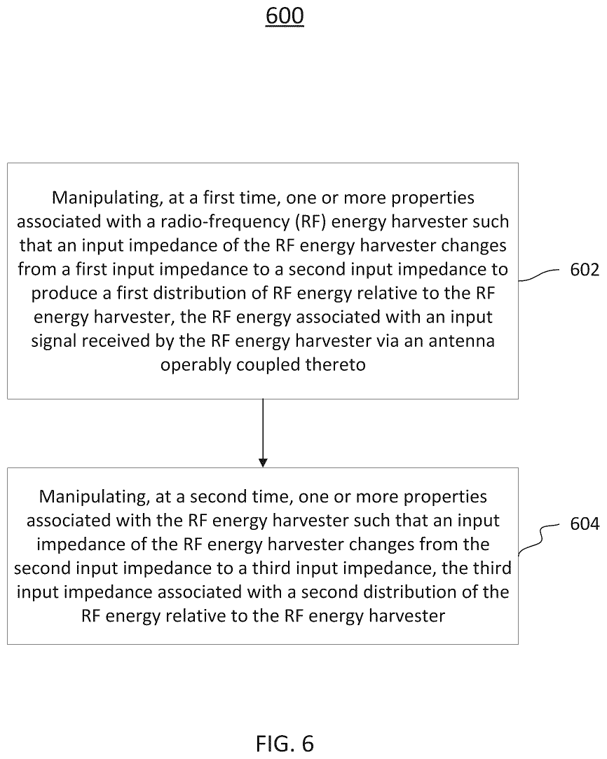

FIG. 6 is a flowchart of a method 600. The method 600 can be, for example, a method of using or operating a system such as any of the systems described herein. The method 600 includes, at step 602, manipulating, at a first time, one or more properties associated with a radio-frequency (RF) energy harvester such that an input impedance of the RF energy harvester changes from a first input impedance to a second input impedance to produce a first distribution of RF energy relative to the RF energy harvester, the RF energy associated with an input signal received by the RF energy harvester via an antenna operably coupled thereto. The first distribution of RF energy can be associated with the second input impedance.

At step 604, one or more properties associated with the RF energy harvester are manipulated at a second time such that an input impedance of the RF energy harvester changes from the second input impedance to a third input impedance, the third input impedance associated with a second distribution of the RF energy relative to the RF energy harvester.

In some embodiments, the third input impedance can be equal to the first input impedance. In some embodiments, the third input impedance can be different from the first input impedance. In some embodiments, the second input impedance is greater than the first input impedance. In some embodiments, the second input impedance is less than the first input impedance. In some embodiments, the third input impedance is greater than the second input impedance and/or the first input impedance. In some embodiments, the third input impedance is less than the second input impedance and/or the first input impedance.

In some embodiments, the RF energy harvester can be configured to receive the input signal from the antenna via a radio-frequency (RF) tuning network, and the manipulating of the one or more properties at the second time can be performed without changing the tuning network.

In some embodiments, the one or more properties can include at least one of a frequency, an input power, or a DC load voltage of the system. In some embodiments, the one or more properties can include a DC output and the manipulating, at the first time, can include transitioning a load coupled to an output of the RF energy harvester from a first load to a second load (e.g., via using any of the systems, apparatus, or methods described herein). In some embodiments, each of the first load and the second load can include one or more load devices, and the transitioning of the load from the first load to the second load can include at least one of electrically coupling an additional load device to the output of the RF energy harvester or electrically decoupling a load device to the output of the RF energy harvester. In some embodiments, the first load includes at least one passive load device, energy storage device, or DC/DC converter. In some embodiments, the second load includes at least one passive load device, energy storage device, or DC/DC converter.

In some embodiments, the first distribution of RF energy includes a first ratio of an amount of energy reflected by the RF energy harvester to an amount of energy directed to the RF energy harvester, and the second distribution of RF energy is a second ratio of the amount of energy reflected by the RF energy harvester to the amount of energy directed to the RF energy harvester.

In some embodiments, the second input impedance or the third input impedance matches an impedance of an RF input of a rectifying circuit associated with the antenna (e.g., of the RF energy harvester or of another device or circuit including a rectifying circuit). In some embodiments, the changing the input impedance of the RF energy harvester from the first input impedance to the second input impedance can produce a mismatch between the input impedance of the RF energy harvester and the antenna.

In some embodiments, the manipulating, at the first time and/or the second time, can include sending a signal to the RF energy harvester to change one or more DC output characteristics of the RF energy harvester. In some embodiments, the signal is one of a digital signal or an analog signal. In some embodiments, the signal is a communications signal. In some embodiments, the signal is configured to change one or more RF input characteristics of the RF energy harvester over time.

In some embodiments, the first distribution of RF energy relative to the RF energy harvester can be associated with RF energy associated with the input signal to be reflected by the RF energy harvester and to by transmitted via the antenna for backscatter communication. In some embodiments, the second distribution of RF energy relative to the RF energy harvester can be associated with at least a portion of the RF energy associated with the input signal being at least one of reflected or directed to an RF device coupled in series or in parallel to the RF energy harvester. In some embodiments, the RF device can be a first RF device, and the first distribution of RF energy relative to the RF energy harvester is associated with at least a portion of the RF energy associated with the input signal being at least one of reflected or directed to a second RF device coupled in series or in parallel to the RF energy harvester. In some embodiments, the first distribution of RF energy relative to the RF energy harvester can be associated with activation of a circuit, and the second distribution of RF energy relative to the RF energy harvester can be associated with providing energy to an RF device coupled to the RF energy harvester.

In some embodiments, the RF energy harvester can be a first RF energy harvester and the RF device can be a second RF energy harvester. In some embodiments, the second RF energy harvester can be operably coupled to the antenna and configured to receive at least a portion of the input signal via the antenna.

In some embodiments, the methods, systems, and apparatus described herein can be the same as or similar to, or can be included in, any suitable system or method (e.g., an energy harvesting system or circuit) in conjunction with any suitable systems, energy harvesting components, features, and/or methods described in any of U.S. Pat. No. 11,394,246, entitled “Powering Devices Using RF Energy Harvesting,” issued Jul. 19, 2022, U.S. Pat. No. 11,245,257, entitled “Method and Apparatus of High Efficiency Rectification for Various Loads,” issued Feb. 8, 2022, U.S. Pat. No. 11,418,234, entitled “Bi-Stable Display Tag,” issued Aug. 16, 2022, U.S. Pat. No. 10,484,111, entitled “Methods, Systems, and Apparatus for Automatic RF Power Transmission and Single Antenna Energy Harvesting,” issued Nov. 19, 2019, U.S. Pat. No. 9,768,711, entitled “RF-DC Power Converter,” issued Sep. 19, 2017, and/or U.S. Pat. No. 11,368,053, entitled “Methods, Systems, and Apparatus for Wireless Recharging of Battery-Powered Devices,” issued Jun. 21, 2022, each of which are incorporated by reference herein. Additionally, any of the components and systems described herein (e.g., tuning networks) can be the same as or similar to any components or systems (e.g., tuning networks) described in any of the references incorporated above.

As used herein, the singular forms “a,” “an” and “the” include plural referents unless the context clearly dictates otherwise. Thus, for example, the term “a device” is intended to mean a single device or a combination of devices, “a device” is intended to mean one or more devices, or a combination thereof.

While various embodiments of the invention have been described above, it should be understood that they have been presented by way of example only, and not limitation. Where methods described above indicate certain events occurring in certain order, the ordering of certain events may be modified. Additionally, certain of the events may be performed concurrently in a parallel process, when possible, as well as performed sequentially as described above. While the embodiments have been particularly shown and described, it will be understood that various changes in form and details may be made. Although various embodiments have been described as having particular features and/or combinations of components, other embodiments are possible having any combination or sub-combination of any features and/or components from any of the embodiments described herein. Further, although methods have been described herein in reference to a specific embodiment, the methods can be executed using any suitable device embodiment described herein.

In some embodiments, the systems (or any of its components) described herein (e.g., any of the controllers and/or processors described herein) can include a non-transitory computer-readable medium (also can be referred to as a non-transitory processor-readable medium) having instructions or computer code thereon for performing various computer-implemented operations. The computer-readable medium (or processor-readable medium) is non-transitory in the sense that it does not include transitory propagating signals per se (e.g., a propagating electromagnetic wave carrying information on a transmission medium such as space or a cable). The media and computer code (also can be referred to as code) may be those designed and constructed for the specific purpose or purposes. Examples of non-transitory computer-readable media include, but are not limited to: magnetic storage media such as hard disks, floppy disks, and magnetic tape; optical storage media such as Compact Disc/Digital Video Discs (CD/DVDs), Compact Disc-Read Only Memories (CD-ROMs), and holographic devices; magneto-optical storage media such as optical disks; carrier wave signal processing modules; and hardware devices that are specially configured to store and execute program code, such as Application-Specific Integrated Circuits (ASICs), Programmable Logic Devices (PLDs), Read-Only Memory (ROM) and Random-Access Memory (RAM) devices.

Examples of computer code include, but are not limited to, micro-code or micro-instructions, machine instructions, such as produced by a compiler, code used to produce a web service, and files containing higher-level instructions that are executed by a computer using an interpreter. For example, embodiments may be implemented using imperative programming languages (e.g., C, Fortran, etc.), functional programming languages (Haskell, Erlang, etc.), logical programming languages (e.g., Prolog), object-oriented programming languages (e.g., Java, C++, etc.) or other suitable programming languages and/or development tools. Additional examples of computer code include, but are not limited to, control signals, encrypted code, and compressed code.

Although various embodiments have been described as having particular features and/or combinations of components, other embodiments are possible having a combination of any features and/or components from any of the embodiments where appropriate. Similarly, where methods and/or events described above indicate certain events and/or procedures occurring in certain order, unless the context clearly dictates otherwise, the ordering of certain events and/or procedures may be modified. While the embodiments have been particularly shown and described, it will be understood that various changes in form and details may be made.

1. A apparatus, comprising:
an antenna;
a radio-frequency (RF) tuning network configured to receive an input signal via the antenna;
an RF energy harvester operatively coupled to the RF tuning network and configured to receive an output of the RF tuning network and to produce a direct current (DC) output based on the received output of the RF tuning network; and
a load manipulator coupled to an output of the RF energy harvester and configured to be transitioned between a first configuration and a second configuration to manipulate one or more properties associated with the RF energy harvester such that an input impedance of the RF energy harvester changes from a first input impedance to a second input impedance, the first input impedance associated with a first distribution of RF energy associated with the input signal relative to the RF energy harvester and the second input impedance associated with a second distribution of RF energy associated with the input signal relative to the RF energy harvester.

2. The apparatus of claim 1, wherein, in the first configuration of the load manipulator, a first load is electrically coupled to the output of the RF energy harvester, and in the second configuration of the load manipulator, a second load is electrically coupled to the output of the RF energy harvester, the second load being different from the first load.

3. The apparatus of claim 1, wherein the load manipulator includes a controller configured to selectively electrically couple the first load to the output of the RF energy harvester in the first configuration of the load manipulator and to selectively electrically couple the second load to the output of the RF energy harvester in the second configuration of the load manipulator.

4. The apparatus of claim 1, wherein the load manipulator includes at least one switch configured to transition the load manipulator between the first configuration and the second configuration by selectively coupling one or more loads to the output of the RF energy harvester.

5. The apparatus of claim 1, wherein the load manipulator is configured to dynamically control the input impedance of the RF energy harvester within a range including the first input impedance and the second input impedance.

6. The apparatus of claim 1, wherein the RF tuning network is a first RF tuning network, and the apparatus further comprising:
a second RF tuning network operatively coupled to the antenna; and
a radio frequency identification (RFID) integrated circuit (IC) operatively coupled to the second RF tuning network.

7. An apparatus, comprising:
an antenna;
a radio-frequency (RF) tuning network configured to receive an input signal via the antenna;
an RF energy harvester operatively coupled to the RF tuning network and configured to receive an output of the RF tuning network and to produce a direct current (DC) output based on the received output of the RF tuning network in response to the RF energy harvester having a first input impedance; and
a set of one or more components configured to receive RF energy reflected or directed from the RF energy harvester in response to the RF energy harvester having a second input impedance, a DC output of the RF energy harvester configured to be manipulated to transition the RF energy harvester from having the first input impedance to having the second input impedance.

8. The apparatus of claim 7, wherein:
the RF energy harvester is a first RF energy harvester, and the set of one or more components includes a second RF energy harvester,
the first RF energy harvester is coupled to a first load manipulator configured to manipulate the DC output of the first RF energy harvester and the second RF energy harvester is coupled to a second load manipulator configured to manipulate a DC output of the second RF energy harvester to change an input impedance of the second RF energy harvester.

9. The apparatus of claim 7, wherein:
the set of one or more components includes an RF device operably coupled to the RF tuning network and configured to receive the output of the RF tuning network,
the RF energy harvester is a first RF energy harvester, and the RF device is a second RF energy harvester configured to produce a DC output based on the received output of the RF tuning network and based on RF energy reflected or directed from the first RF energy harvester.

10. The apparatus of claim 7, wherein:
the RF tuning network is a first RF tuning network, and the set of one or more components includes a second RF tuning network and an RF device operably coupled to the second RF tuning network, the second RF tuning network configured to receive an input signal via the antenna and the RF device configured to receive an output of the second RF tuning network,
the RF energy harvester is a first RF energy harvester, and the RF device is a second RF energy harvester configured to produce a DC output based on the received output of the second RF tuning network and based on RF energy reflected or directed from the first RF energy harvester.

11. The apparatus of claim 7, further comprising:
a circuit operably coupled to the output of the RF energy harvester and configured to be activated by the DC output produced by the RF energy harvester when the RF energy harvester has a first set of one or more DC output characteristics associated with the first input impedance,
the RF energy harvester being configured to be manipulated to transition the RF energy harvester to have the second input impedance by changing the RF energy harvester from having the first set of one or more DC output characteristics to having a second set of one or more DC output characteristics associated with the second input impedance.

12. The apparatus of claim 7, wherein the RF energy harvester is configured to change from having the first set of one or more DC output characteristics to having the second set of one or more DC output characteristics in response to an activation of the circuit operably coupled to the output of the RF energy harvester.

13. A method, comprising:
manipulating, at a first time, one or more properties associated with a radio-frequency (RF) energy harvester such that an input impedance of the RF energy harvester changes from a first input impedance to a second input impedance to produce a first distribution of RF energy relative to the RF energy harvester, the RF energy associated with an input signal received by the RF energy harvester via an antenna operably coupled thereto; and
manipulating, at a second time, the one or more properties associated with the RF energy harvester such that an input impedance of the RF energy harvester changes from the second input impedance to a third input impedance, the third input impedance associated with a second distribution of the RF energy relative to the RF energy harvester.

14. The method of claim 13, wherein the RF energy harvester is configured to receive the input signal from the antenna via a radio-frequency (RF) tuning network, and the manipulating of the one or more properties at the second time is performed without changing the RF tuning network.

15. The method of claim 13, wherein at least one of the one or more properties manipulated at the first time or the one or more properties manipulated at the second time includes at least one of a frequency, an input power, or a DC load voltage.

16. The method of claim 13, wherein:
at least one of the one or more properties manipulated at the first time or the one or more properties manipulated at the second time includes a DC output, and
the manipulating, at the first time, includes transitioning a load coupled to an output of the RF energy harvester from a first load to a second load.

17. The method of claim 16, wherein:
each of the first load and the second load includes one or more load devices, and
the transitioning of the load from the first load to the second load includes at least one of electrically coupling an additional load device to the output of the RF energy harvester or electrically decoupling a load device to the output of the RF energy harvester.

18. The method of claim 13, wherein:
the first distribution of RF energy is associated with a first ratio of an amount of energy reflected by the RF energy harvester to an amount of energy directed to the RF energy harvester, and
the second distribution of RF energy is associated with a second ratio of the amount of energy reflected by the RF energy harvester to the amount of energy directed to the RF energy harvester.

19. The method of claim 13, wherein:
the second distribution of RF energy relative to the RF energy harvester is associated with at least a portion of the RF energy associated with the input signal being at least one of reflected or directed to a first RF device coupled to the RF energy harvester,
the first distribution of RF energy relative to the RF energy harvester is associated with at least a portion of the RF energy associated with the input signal being at least one of reflected or directed to a second RF device coupled to the RF energy harvester.

20. The method of claim 13, wherein:
the first distribution of RF energy relative to the RF energy harvester is associated with activation of a circuit, and
the second distribution of RF energy relative to the RF energy harvester is associated with providing energy to an RF device coupled to the RF energy harvester.
